(19) United States
(12) Patent Application Publication
(10) Pub. No.: US 2003/0038338 A1
(43) Pub. Date: Feb. 27, 2003

(54) Semiconductor device incorporating a fuse

(75) Inventors: Richard Fournel, Lumbin (FR); Norbert Colombet, Domene (FR); Phillippe Candelier, Saint Mury (FR)

Correspondence Address: ALLEN, DYER, DOPPELT, MILBRATH & GILCHRIST P.A., 1401 CITRUS CENTER 255 SOUTH ORANGE AVENUE, P.O. BOX 3791, ORLANDO, FL, 32802-3791, US

(73) Assignee: STMicroelectronics S.A., Montrouge (FR)

(21) Appl. No.: 10/179,462

(22) Filed: Jun. 25, 2002

(30) Foreign Application Priority Data
Jun. 26, 2001 (FR) 0108427

(51) Int. Cl. H01L 29/00

(52) U.S. Cl. 257/529

(57) ABSTRACT

A semiconductor device includes multiple layers of integrated electronic components, and at least one electrical connection strip defining a fusible strip in one of the layers. An end of the fusible strip is connected to an integrated electronic component. An intermediate electrical connection and heat dissipation structure and a screen are disposed between the fusible strip and the integrated electronic component.

### FIELD OF THE INVENTION

The present invention relates to semiconductor devices, and in particular, to a semiconductor device incorporating multiple layers of integrated electronic components.

### BACKGROUND OF THE INVENTION

Providing a semiconductor device with electrical connection strips connecting integrated electronic components, and forming fuses for selectively programming the device by blowing the fuses or leaving them in place is known in the art. This applies, in particular, when it is required to isolate electronic components, such as transistors.

Rupturing or blowing the fusible strips with laser beams is known in the art. Using laser beams generates heat in the environment of the fusible strips, which can degrade integrated electronic components near the fusible strips by conduction or radiation.

### SUMMARY OF THE INVENTION

In view of the foregoing background, an object of the present invention is to blow fuse strips without degrading integrated electronic components near the fuse strips.

This and other objects, advantages and features in accordance with the present invention are provided by a semiconductor device including multiple layers of integrated electronic components, and in at least one layer, at least one electrical connection strip forming a fuse that can be blown, and at least one end of which is connected to at least one integrated electronic component.

Intermediate electronic connection means and heat dissipation means are disposed between the fusible strip and the integrated electronic component. The intermediate means preferably include at least one serpentine electrical connection strip. The electrical connection strip is preferably connected to the fusible strip through the heat dissipation means. The intermediate means preferably include heat dissipation strips in different layers and connected by vias. The thermal dissipation strips are preferably parallel to the fusible strip.

The semiconductor device can advantageously include at least one electrically insulated thermal screen in the immediate environment of the fusible strip. The screen is preferably between the fusible strip and the intermediate means. The intermediate means can advantageously pass through the screen.

The screen preferably includes strips at a distance from each other, in different layers, one above the other, connected by vias and perpendicular to the fusible strip. The semiconductor device can advantageously include at least one protection diode connected to the intermediate electrical connection means.

### BRIEF DESCRIPTION OF THE DRAWINGS

The present invention will be better understood after studying a semiconductor device with fusible strips described by way of non-limiting examples and shown in the drawings, in which:

FIG. 1 is a partial longitudinal sectional view of a semiconductor device according to the present invention;

FIG. 2 shows the semiconductor device from FIG. 1 in a cross-sectional taken along line II-II;

FIG. 3 shows the semiconductor device from FIG. 1 in a cross-sectional view taken along line III-III;

FIG. 4 shows the semiconductor device from FIG. 1 in a cross-sectional view taken along line IV-IV; and

FIG. 5 is a plan view and partly a sectional view of the semiconductor device from FIG. 1 taken along line V-V.

### DETAILED DESCRIPTION OF THE PREFERRED EMBODIMENTS

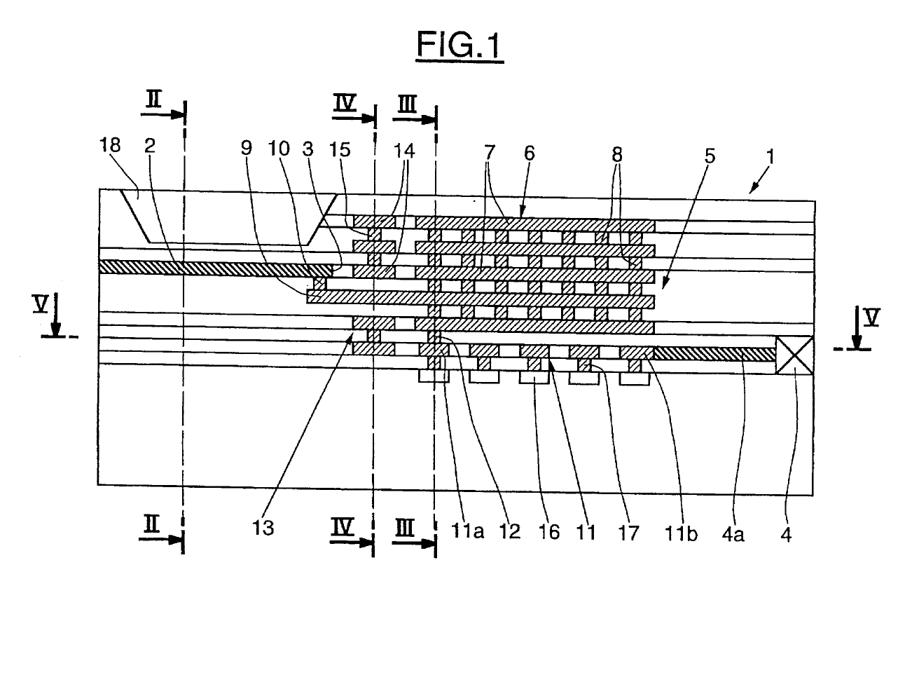

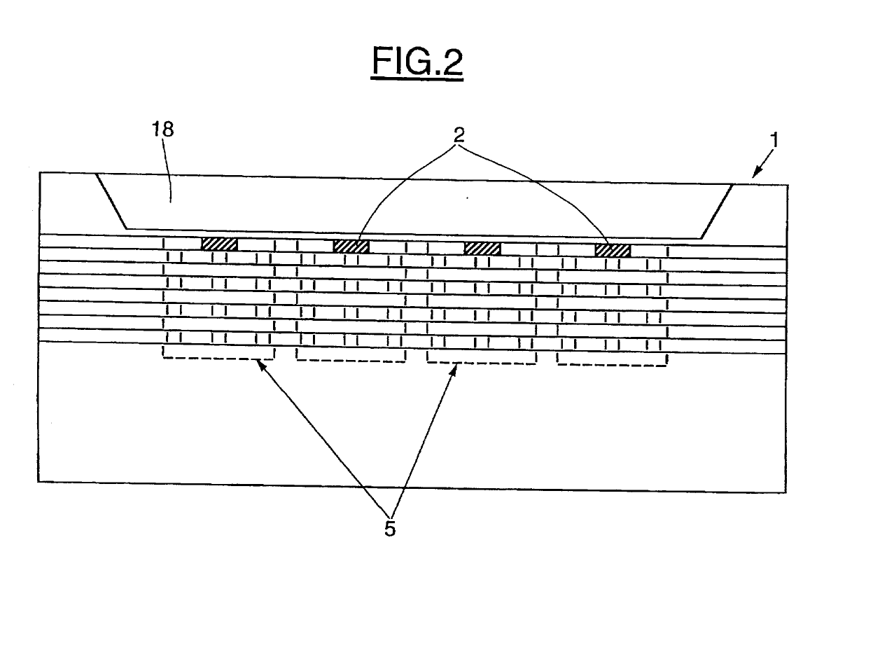

Referring in particular to FIGS. 1 and 2, a semiconductor device 1 with multiple layers of integrated electronic components is illustrated, which includes four, for example, narrow longitudinal electrical connecting strips forming fuses. The fusible strips 2 are formed at a distance from each other in a middle layer of the device 1.

In the example shown, the semiconductor device 1 includes four integrated electronic components 4, such as NMOS or PMOS transistors possibly driving a memory, at a distance from a corresponding end 3 of the fusible strips 2 and longitudinally disposed with respect thereto. The other ends of the fusible strips 2 are connected to ground, for example.

The ends 3 of the fusible strips 2 are connected to respective integrated electronic components 4 by four, for example, intermediate electrical connection and thermal dissipation means 5 disposed at a distance from each other and arranged side by side.

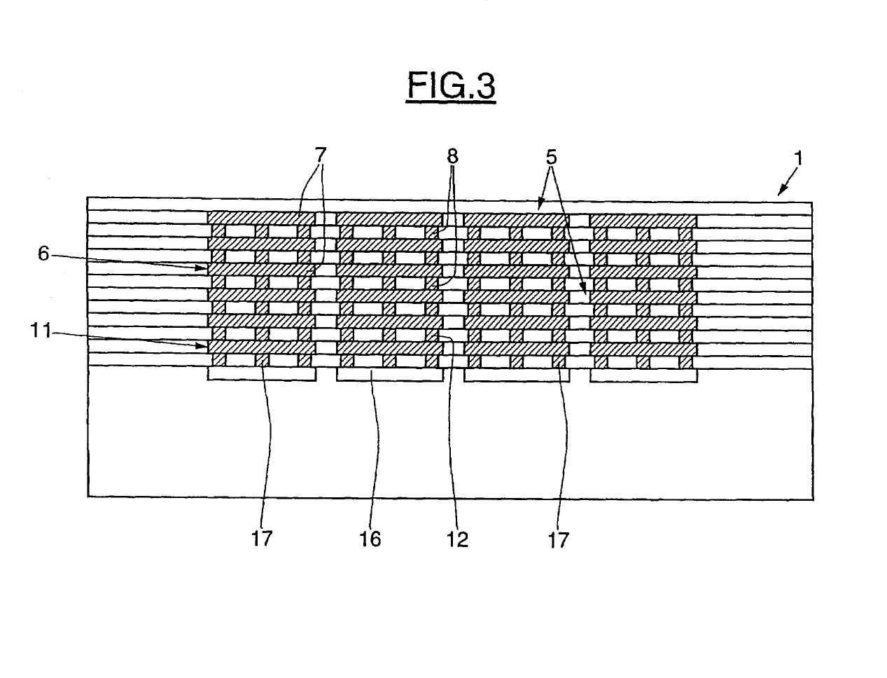

As shown more particularly in FIGS. 1 and 3, the intermediate means 5 include a main thermal dissipation block 6 within the volume of the semiconductor device 1 between the ends 3 of the fusible strips 2 and the integrated electronic components 4. In this example the main thermal dissipation block 6 includes five wide longitudinal strips 7 disposed at a distance from each other and one above the other, with multiple vias connecting the adjacent wide strips 7.

One longitudinal strip 7, for example, an intermediate strip of each intermediate means 5, has a longitudinal extension 9 toward the corresponding fusible strip 2 and is located below its end 2a. The extensions 9 of the intermediate means 5 are connected to the ends 3 of the respective fusible strips 2 by vias 10.

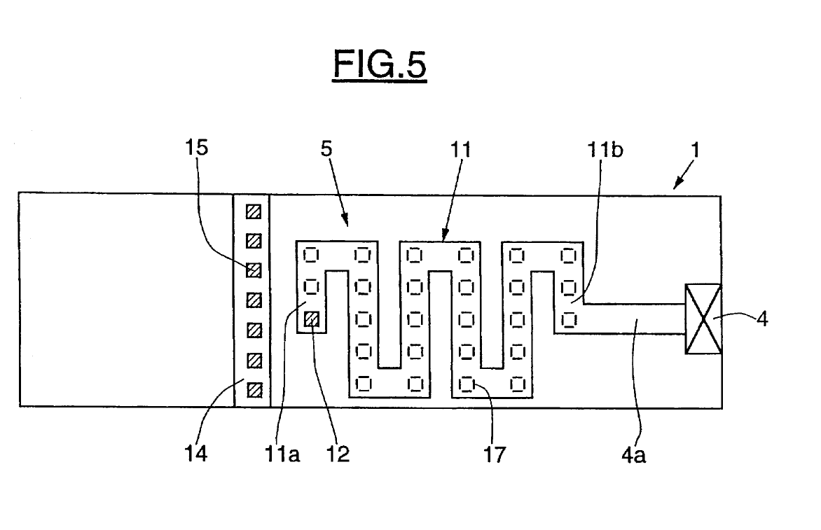

As shown more particularly in FIGS. 1, 3 and 5, the intermediate means 5 further include electrical connecting strips 11 disposed under and at a distance from the blocks. The electrical connecting strips 11 extend longitudinally in a serpentine manner. The ends 11a of the serpentine strips 11 adjoining the corresponding fusible strips 2 are connected to the adjacent wide strips 7 by vias 12 and their ends 11b adjoining the integrated electronic components 4 that are respectively connected thereto by longitudinal electrical connecting branches 4a.

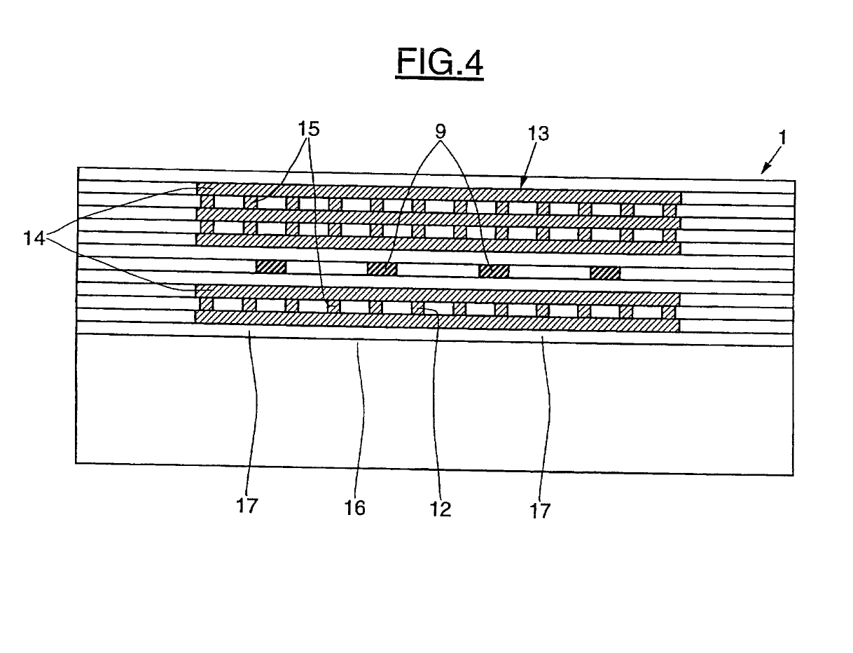

As shown more particularly in FIGS. 1 and 4, the semiconductor device 1 further includes an electrically insulated screen 13 disposed between and at a distance from the ends 3 of the fusible strips 2 and the intermediate means 5. The extensions 9 pass through the screen 13. The screen 13 extends substantially over the width defined by the four intermediate means 5 and on either side of the plane defined by the fusible strips 2, and therefore extends substantially over the thickness of the intermediate means 5. In the example shown, the screen 13 includes five transverse wide strips 14 disposed at a distance from and above each other and connected by respective vias 15.

The semiconductor device 1 further includes diodes 16 placed under the electrically connecting serpentine strips 11 and are connected to respective branches thereof by vias 17. The strips and the vias previously discusses are preferably made of metal or of any other material that is a good conductor of electricity.

The fusible strips 2, the branches and the vias forming the intermediate means 5 and the screen 13 and the connecting branches 4a are buried in layers of dielectric material and are fabricated in a conventional manner. In addition, the semiconductor device 1 has no integrated electronic components in the immediate peripheral environment of the fusible strips 2, and incorporates a recess 18 such that there is only a small thickness of dielectric above them.

The semiconductor device 1 just described has the following advantages. When the semiconductor device 1 is in the state previously described, the fusible strips 2 are electrically connected to the respective electronic integrated components 4 through the extensions 9 by the vias 10, through the wedge-shaped portion of the thermal dissipation block 6 directly connecting the extensions 9 and the vias 12, through the electrical connection serpentine strip 11 by the vias 12, and through the electrical connection branches 4a. The integrated electronic components 4 are therefore electrically connected to the electronic components connected to the other ends of the fusible strips 2.

When a fusible strip 2 is ruptured or blown to electrically isolate the corresponding electronic component 4, for example, by a laser beam directed toward the bottom of the recess 18, the corresponding intermediate means 5 and the screen 13 provide protection against conducted or radiated heat, so that the latter cannot damage surrounding integrated electronic components, in particular the corresponding integrated electronic component 4.

The conducted heat travels along the extension 9 and through the vias 10 toward the thermal dissipation block 6, and the serpentine strip 11 connected to the thermal dissipation block 6 by the vias 12 forming a barrier to dissipate the residual heat. Also, the screen 13 forms a thermal barrier to block radiated heat. In addition, the diodes 16 provide electrical protection against the electrical charges generated.

The present invention is not limited to the example described above. It lends itself to many different embodiments that do not depart from the scope of the accompanying claims.

That which is claimed is:

1. A semiconductor device including multiple layers of integrated electronic components and, in at least one layer, at least one electrical connection strip constituting a fuse, disposed so that it can be ruptured, and at least one end of which is connected to at least one integrated electronic component, characterized in that intermediate electronic connection and heat dissipation means (5) are disposed between said fusible strip (2) and said integrated electronic component (4).

2. A device according to claim 1, characterized in that said intermediate means (5) include at least one serpentine electrical connection strip (11).

3. A device according to claim 2, characterized in that said electrical connection strip (11) is connected to said fusible strip (2) through heat dissipation means (6).

4. A device according to any preceding claim, characterized in that said intermediate means (5) include heat dissipation strips (7) in different layers and connected by vias (8).

5. A device according to claim 4, characterized in that said thermal dissipation strips (7) are parallel to said fusible strip (2).

6. A device according to any preceding claim, characterized in that it includes at least one electrically insulated thermal screen (13) in the immediate environment of said fusible strip (2).

7. A device according to claim 6, characterized in that said screen (13) is between said fusible strip (2) and said intermediate means (5).

8. A device according to claim 6, characterized in that said intermediate means (5) pass through said screen (13).

9. A device according to any of claims 6 to 8, characterized in that said screen (13) includes strips (14) at a distance from each other, in different layers, one above the other, connected by vias (15) and 5 perpendicular to said fusible strip (2).

10. A device according to any preceding claim, characterized in that it includes at least one protection diode (16) connected to said intermediate electrical connection means (11).
